(19) United States
(12) Patent Application Publication
(10) Pub. No.: US 2024/0071789 A1
(43) Pub. Date: Feb. 29, 2024

(54) SEMICONDUCTOR MANUFACTURING APPARATUS AND METHOD OF MANUFACTURING SEMICONDUCTOR DEVICE

(71) Applicant: Kioxia Corporation, Tokyo (JP)

(72) Inventors: Shoma OMURA, Kuwana Mie (JP); Takanobu ONO, Kuwana Mie (JP)

(21) Appl. No.: 18/453,949

(22) Filed: Aug. 22, 2023

(30) Foreign Application Priority Data
Aug. 24, 2022 (JP) 2022-133657

(51) Int. Cl. H01L 21/67

(52) U.S. Cl. CPC H01L 21/67132; H01L 21/67259; H01L 21/6836

(57) ABSTRACT

According to one embodiment, a semiconductor manufacturing apparatus includes a plurality of clamping portions and a control unit. Each of the plurality of clamping portions has a first rotating body and a second member. The clamping portions clamp a sheet on which a wafer is mounted. The clamping portions are positioned around an circumferential position of the wafer. The control unit controls rotation of each first rotating body of the plurality of clamping portions to pull the sheet outwardly to increase the distance between individualized chips of the wafer.

### CROSS-REFERENCE TO RELATED APPLICATION(S)

This application is based upon and claims the benefit of priority from Japanese Patent Application No. 2022-133657, filed Aug. 24, 2022, the entire contents of which are incorporated herein by reference.

### FIELD

Embodiments described herein relate generally to a semiconductor manufacturing apparatus and a method of manufacturing a semiconductor device.

### BACKGROUND

In a post-process in semiconductor manufacturing, an expanding process may be performed to expand a gap left between individualized chips cut from a wafer or the like. In the expanding process, it is desirable to expand an interval of the chips more appropriately.

### BRIEF DESCRIPTION OF THE DRAWINGS

FIG. 1 is a diagram illustrating an example of a configuration of a semiconductor manufacturing apparatus according to a first embodiment.

FIG. 2 is a diagram illustrating an example of positioning of clamping portions according to a first embodiment.

FIG. 3 is a diagram illustrating an example of a configuration of a clamping portion and an expanding tape according to a first embodiment.

FIG. 4A is a perspective view illustrating aspects of a method of manufacturing a semiconductor device according to the first embodiment.

FIG. 4B is a perspective view illustrating aspects of a method of manufacturing a semiconductor device.

FIG. 4C is a perspective view illustrating aspects of a method of manufacturing a semiconductor device.

FIG. 4D is a perspective view illustrating aspects of a method of manufacturing a semiconductor device.

FIG. 5A is a diagram illustrating aspects of a method of manufacturing a semiconductor device.

FIG. 5B is a diagram illustrating aspects of a method of manufacturing a semiconductor device.

FIG. 5C is a diagram illustrating aspects of a method of manufacturing a semiconductor device.

FIG. 5D is a diagram illustrating aspects of a method of manufacturing a semiconductor device.

FIG. 6A is a diagram illustrating aspects of a method of manufacturing a semiconductor device according to a comparative example.

FIG. 6B is a diagram illustrating aspects of a method of manufacturing a semiconductor device according to a comparative example.

FIG. 6C is a diagram illustrating aspects of a method of manufacturing a semiconductor device according to a comparative example.

FIG. 7 is a diagram illustrating an example of a shape of a semiconductor chip according to Modified Example.

FIG. 8 is a diagram illustrating an example of positioning of clamping portions according to a second embodiment.

FIG. 9 is a diagram illustrating an example of positioning of clamping portions according to a third embodiment.

### DETAILED DESCRIPTION

Embodiments provide a semiconductor manufacturing apparatus and a method of manufacturing a semiconductor device capable of more appropriately expanding a distance between chips.

In general, according to one embodiment, a semiconductor manufacturing apparatus includes a plurality of clamping portions positioned around an outer circumferential position of a wafer and configured to pull a sheet, to which the wafer is mounted, outwardly from a central portion of the wafer. Each clamping portion includes a first rotating body paired with a second body for clamping the sheet. A control unit is configured to control the rotation of each first rotating body of the plurality of clamping portions to pull the sheet outwardly.

Hereinafter, certain example embodiments will be described with reference to the drawings. These example embodiments do not limit present disclosure. The drawings are schematic or conceptual, and depicted dimensions, ratios in dimensions of different components, and the like is not necessarily the same as in an actual implementation. In the specification and drawings, the same elements as those described for a previous drawing are subsequently denoted by the same reference numerals, and additional description thereof may be omitted as appropriate.

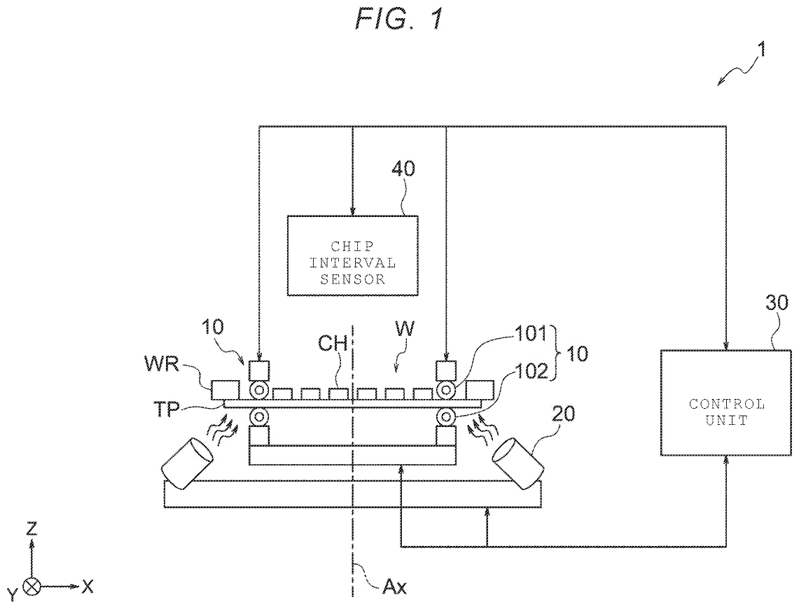

FIG. 1 is a diagram illustrating an example of a configuration of a semiconductor manufacturing apparatus 1 according to a first embodiment.

The semiconductor manufacturing apparatus 1 includes a plurality of clamping portions 10, a heating unit 20, a control unit 30, and a chip interval detection unit 40.

The plurality of clamping portions 10 nip (clamp) an expanding tape TP at a plurality of positions on an outer circumference of a semiconductor wafer W. The semiconductor wafer W has been individualized (singulated/diced) into a plurality of semiconductor chips CH and this plurality of semiconductor chips is still attached to the expanding tape TP. Each clamping portion 10 includes, for example, a pair of rotating bodies (rollers). The pair of rotating bodies includes an upper rotating body 101 and a lower rotating body 102. The upper rotating body 101 and the lower rotating body 102 are, for example, rollers. The upper rotating body 101 and the lower rotating body 102 face each other and clamp the expanding tape TP. In an example illustrated in FIG. 1, a plurality of lower rotating bodies 102 are disposed on one table or mount.

The semiconductor wafer W is initially attached to a central portion of the expanding tape TP. As will be described later, this semiconductor wafer W is then individualized into the plurality of semiconductor chips CH. A wafer ring WR is attached to an outer circumference of the expanding tape TP. The expanding tape TP is a continuous sheet or film. The surface of the semiconductor wafer W on which devices are formed may be attached to the expanding tape TP or the surface of the semiconductor wafer W opposite to the surface on which devices are formed may be attached to the expanding tape TP.

At least two clamping portions 10 are disposed on opposite sides of the semiconductor wafer W, as illustrated in FIG. 1. The rotating directions of the upper rotating bodies 101 of the two clamping portions 10 are opposite to each other. The rotating directions of the lower rotating bodies 102 of the two clamping portions 10 are opposite to each other. Therefore, as the upper rotating body 101 and the lower rotating body 102 rotate, the expanding tape TP is veered out and pulled outwardly (expanded) by the action of the pair of rotating bodies 101, 102. As a result, the interval (distance) between the individual semiconductor chips CH can be expanded.

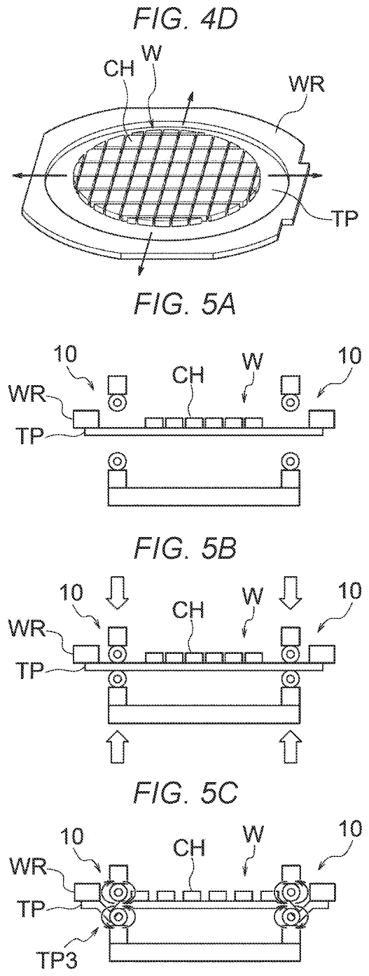

The heating unit 20 heats the expanding tape TP at the outer circumference of the semiconductor wafer W. More specifically, the heating unit 20 heats the expanding tape TP on the outer circumference of the semiconductor wafer W during or after the veering out of the expanding tape TP. The heating unit 20 heats a relaxing portion of the expanding tape TP formed by veering out the expanding tape TP (refer to FIGS. 5C and 5D). Accordingly, the expanded interval between the semiconductor chips CH can be maintained. The heating unit 20 includes a heat source such as a heat gun or an infrared heater. The heating unit 20 may be controlled by, for example, the control unit 30. In the example illustrated in FIG. 1, two heating units 20 are provided, but the number of heating units 20 may be one, or three or more.

The heating unit 20 in some examples may be rotatable about the central axis Ax that passes through substantially the center of the semiconductor wafer W. This can be beneficial because the relaxing portion to be heated is formed in a substantially circular shape according to the shape of the semiconductor wafer W.

The upper rotating body 101, the lower rotating body 102, and the heating unit 20 can be moved (lifted/lowered) by different driving mechanisms.

The control unit 30 controls the clamping portions 10. The control unit 30 controls rotation, ascent, and descent of the upper rotating body 101. The control unit 30 controls rotation, ascent, and descent of the lower rotating body 102. The control unit 30 controls the rotation of the upper rotating body 101 and the lower rotating body 102 so as to veer out (send out) the expanding tape TP outwardly from the semiconductor wafer W. That is, the control unit 30 rotates the upper rotating body 101 and the lower rotating body 102 to veer out the expanding tape TP from the center of the semiconductor wafer W to the outer peripheral side. Accordingly, the interval between the semiconductor chips CH can be expanded more appropriately. For example, the control unit 30 is a processor, a microprocessor, a computer, or the like.

The control unit 30 controls the upper rotating body 101 and the lower rotating body 102 based on various design parameters. These parameters are related to adjustment of the load on the expanding tape TP. The parameters include, for example, the number of rotations (rotational speed), an amount of ascent, and an amount of descent of each of the upper rotating body 101 and the lower rotating body 102. The number of rotations corresponds to, for example, the nominal veering out length of the expanding tape TP. The amount of ascent and the amount of descent correspond to, for example, the force that clamps the expanding tape TP.

The parameters may be set individually for each clamping portion 10. When feedback control (automatic adjustment of parameters) is performed, the preset parameters may be the same for all the clamping portions 10.

The chip interval detection unit 40 detects the current interval (distance) between the semiconductor chips CH. The chip interval detection unit 40 detects the interval between the semiconductor chips CH by, for example, scanning with the laser. The chip interval detection unit 40 transmits the measured interval between adjacent semiconductor chips CH to the control unit 30. The control unit 30 automatically adjusts the parameters based on the detection result (measurement) from the chip interval detection unit 40 and controls the rotation of the upper rotating body 101 and the lower rotating body 102 as appropriate. Accordingly, feedback control (automatic adjustment of the parameters) can be performed for each clamping portion 10 based on the measured interval between the semiconductor chips CH. The automatic adjustment of the parameters is performed, for example, so that deviations or variations in the intervals are reduced.

In some examples, the chip interval detection unit 40 may be an imaging unit acquiring photographs, video, or images of the plurality of semiconductor chips CH. In such a case, the control unit 30 calculates the interval between the semiconductor chips CH based on analysis of the image(s) transmitted from the imaging unit.

Next, the details of the clamping portion 10 will be described.

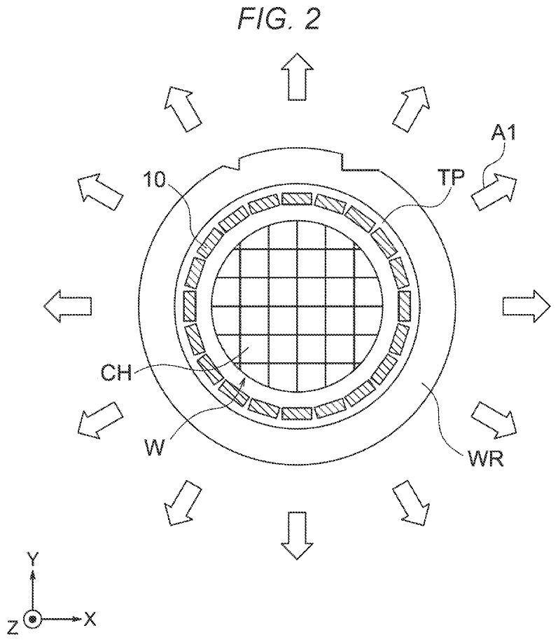

FIG. 2 is a diagram illustrating an example of positioning of the clamping portions 10 according to the first embodiment.

In the example illustrated in FIG. 2, the plurality of clamping portions 10 are disposed concentrically with respect to the semiconductor wafer W. The plurality of clamping portions 10 are disposed in a line along the outer circumference of the semiconductor wafer W between the semiconductor wafer W and the wafer ring WR.

The arrows A1 illustrated in FIG. 2 indicates the direction for expanding the interval between the semiconductor chips CH, that is, the direction of pulling the expanding tape TP.

The control unit 30 controls the rotation of the upper rotating body 101 and the lower rotating body 102 for each clamping portion 10 according to the direction parallel to the surface of the expanding tape TP. The control unit 30 may control the upper rotating body 101 and the lower rotating body 102 independently for each clamping portion 10. Accordingly, different rotation control can be performed for each in-plane direction of the expanding tape TP. As a result, the pulling for on the expanding tape TP can be changed according to the in-plane direction for the expanding tape TP.

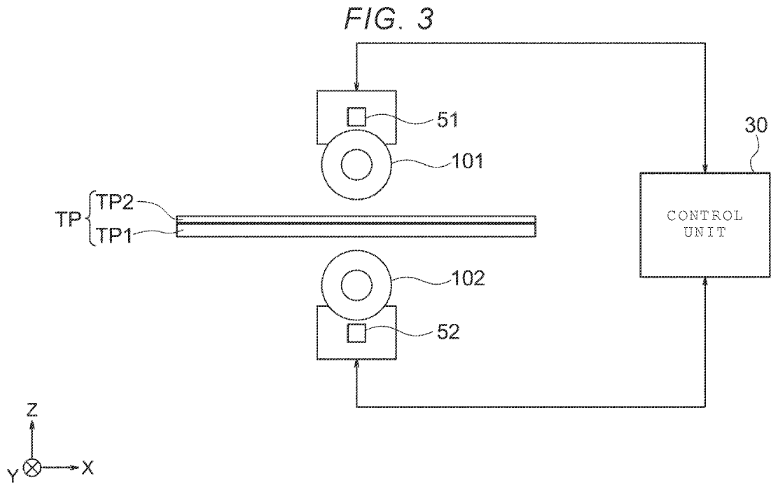

FIG. 3 is a diagram illustrating an example of a configuration of a clamping portion 10 and the expanding tape TP according to the first embodiment.

The semiconductor manufacturing apparatus 1 further includes load detection units 51, 52.

The load detection units 51, 52 respectively detect loads on the upper rotating body 101 and the lower rotating body 102. The upper load detection unit 51 detects the load of the upper rotating body 101. The lower load detection unit 52 detects the load of the lower rotating body 102.

The load detection units 51, 52 transmit a load detection result to the control unit 30. The control unit 30 automatically adjusts the parameters based on the load detection results and adjusts (controls) the rotation of the upper rotating body 101 and the lower rotating body 102 as appropriate. The control unit 30 automatically adjusts the parameters based on the detection result of the upper load detection unit 51 and controls the upper rotating body 101. The control unit 30 automatically adjusts parameters based on the detection result of the lower load detection unit 52 and controls the lower rotating body 102. Accordingly, feedback control (automatic adjustment of the parameters) can be performed for each clamping portion 10 based on the detected loads. The automatic adjustment of the parameters is performed, for example, so that any deviation in the load among the clamping portions 10 is reduced.

As illustrated in FIG. 3, the expanding tape TP includes a substrate TP1 and an adhesive layer TP2.

The adhesive layer TP2 is provided on the substrate TP1. The adhesive layer TP2 is provided for attaching the semiconductor wafer W to the expanding tape TP.

The upper rotating body 101 is in contact with the adhesive layer TP2 when the clamping portion 10 clamps the expanding tape TP. The lower rotating body 102 is in contact with the substrate TP1 when the clamping portion 10 clamps the expanding tape TP. Therefore, the upper rotating body 101 and the lower rotating body 102 may be made of different materials.

The upper rotating body 101 is preferably made of a material that is less likely to adhere dirt and the like as compared to the lower rotating body 102. The material of the upper rotating body 101 is, for example, teflon, polyethylene, silicon rubber, or the like. The lower rotating body 102 is preferably made of a material that is less slippery (higher friction) than the upper rotating body 101 so the veering out of the expanding tape TP can be facilitated. The material of the lower rotating body 102 is, for example, low-density polyethylene, vinyl chloride, or the like. The material of the lower rotating body 102 may be metal or the like in other examples. The lower rotating body 102 may be subjected to surface treatment such as a roughening of the surface to allow the surface to be less slippery.

Next, the method of manufacturing a semiconductor device will be described.

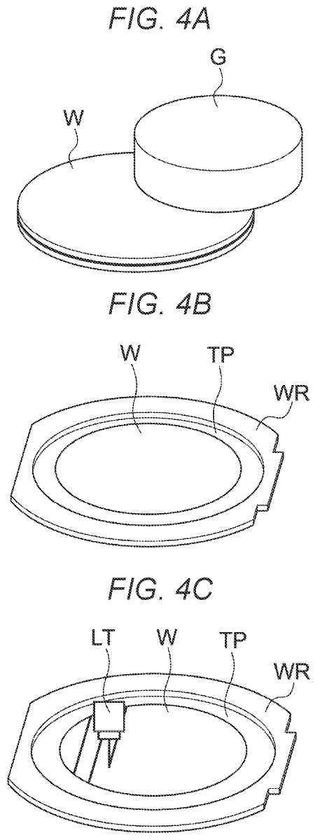

FIGS. 4A to 4D are perspective views illustrating an example of the method of manufacturing a semiconductor device according to the first embodiment.

First, as illustrated in FIG. 4A, the back surface of the semiconductor wafer W is ground by a grinder G.

Next, as illustrated in FIG. 4B, the flexible expanding tape TP is attached to the back surface of the semiconductor wafer W and the wafer ring WR.

Next, as illustrated in FIG. 4C, a laser beam is scanned along a dicing line on a front surface or a back surface of the semiconductor wafer W by using a laser oscillator LT. The semiconductor wafer W is individualized into semiconductor chips CH by this laser dicing process.

Next, as illustrated in FIG. 4D, the interval between the individualized semiconductor chips CH is expanded. By expanding the interval between the semiconductor chips CH, the semiconductor chips CH can be prevented from coming into contact with each other during pickup or the like. Each semiconductor chip CH is picked up from the expanding tape TP to be eventually mounted in a final assembly, package, or the like.

It should be noted that the processes illustrated in FIGS. 4A to 4C are not necessarily limited to this described order.

Next, details of the expanding process in FIGS. 5A to 5D will be described.

FIGS. 5A to 5D are diagrams illustrating an example of a method of manufacturing a semiconductor device according to the first embodiment.

As illustrated in FIG. 5A, the semiconductor wafer W is carried (loaded) into the semiconductor manufacturing apparatus 1.

Next, as illustrated in FIG. 5B, each clamping portion 10 clamps the expanding tape TP between the pairs of rotating bodies. More specifically, the upper rotating body 101 descends, and the lower rotating body 102 ascends. Accordingly, each clamping portion 10 clamps the expanding tape TP in the region between the semiconductor wafer W and the wafer ring WR.

Next, as illustrated in FIG. 5C, the upper rotating body 101 and the lower rotating body 102 rotate to veer out the expanding tape TP. Accordingly, the expanding tape TP is pulled from the central portion outwardly, and the interval between the semiconductor chips CH is expanded. That is, the control unit 30 rotates the upper rotating body 101 and the lower rotating body 102 to veer out the expanding tape TP from the semiconductor wafer W. A relaxing portion TP3 is formed in the expanding tape TP in a region between the clamping portion 10 and the wafer ring WR.

Next, as illustrated in FIG. 5D, the heating unit 20 heats the relaxing portion TP3 of the expanding tape TP in the region between the clamping portion 10 and the wafer ring WR. Accordingly, the relaxing portion TP3 of the expanding tape TP shrinks by thermal contraction. As a result, the interval between the semiconductor chips CH expanded in the tape expanding process of FIG. 5C (expanded state of the tape) can be more easily maintained. In general, the heating unit 20 is provided integrated in the same device as the clamping portions 10, although the depiction of the heating unit 20 was omitted in FIGS. 5A to 5C. The expanding tape TP can thus be heated while the interval between the semiconductor chips CH is being expanded.

It should be noted that the heating of the relaxing portion TP3 may be performed after veering out of the expanding tape TP. Even then, the semiconductor wafer W is not conveyed from the veering out of the expanding tape TP to the heating of the relaxing portion TP3.

After this interval expansion process, the semiconductor wafer W is unloaded. The semiconductor chips CH of the semiconductor wafer W can then be picked up by another apparatus. In some examples of the semiconductor manufacturing apparatus 1, mechanisms for the semiconductor chips CH to be picked up may be integrated. In some examples, a ultraviolet (UV) light may be irradiated from the substrate TP1 side of the expanding tape TP to cure the adhesive layer TP2 of the expanding tape TP, so that picking up the semiconductor chip CH is facilitated. In other examples, the expanding tape TP may instead, or in addition, be cooled to harden the adhesive layer TP2.

As described above, according to the first embodiment, each clamping portion 10 includes the upper rotating body 101 and the lower rotating body 102. The plurality of clamping portions 10 clamp the expanding tape TP on the outer circumference of the semiconductor wafer W. The control unit 30 controls the rotation of the upper rotating body 101 and the lower rotating body 102 to veer out (pull) the expanding tape TP outwardly from center region of the semiconductor wafer W. Accordingly, the interval between the semiconductor chips CH can be expanded more appropriately, such as more uniformly and/or to a greater amount.

The clamping portions 10 are disposed between the semiconductor wafer W and the wafer ring WR. Even when the space between the semiconductor wafer W and the wafer ring WR is narrow and it is difficult to control the pulling of the expanding tape TP in an XY plane, the expanding tape TP can still be horizontally veered, so that the expansion of the interval between the semiconductor chips CH can be controlled more appropriately.

It should be noted that, in the first embodiment, the control unit 30 controls the rotational driving of both the upper rotating body 101 and the lower rotating body 102. However, the control unit 30 may optionally control the rotational driving of either one of the upper rotating body 101 and the lower rotating body 102. It should be noted that the other rotating body can be rotated according to the rotational driving of the one rotating body.

In the first embodiment, each clamping portion 10 includes a pair of rotating bodies. However, in other examples, the clamping portions 10 may comprise one rotating body and one a non-rotating member rather than another rotating body. For example, in FIG. 3, the upper rotating body 101 on the adhesive layer TP2 side may be a non-rotating member simply facing the lower rotating body 102.

In the first embodiment, the shapes of the upper rotating body 101 and the lower rotating body 102 are substantially circular. However, the upper rotating body 101 and the lower rotating body 102 may have a difference in shape. The shape of the upper rotating body 101 may be, for example, a star shape or sprocket shape including the plurality of projection portions. The upper rotating body 101 and the lower rotating body 102 may have a difference in size (e.g., diameter or axial length). For example, the driving force may change depending on the size of the rotating body.

The heating unit 20 may be provided in the clamping portion 10 or may be integrated in the clamping portion 10. Here, for example, the expanding tape TP can be heated by allowing the upper rotating body 101 or the lower rotating body 102 heated by a heater when in contact with the expanding tape TP.

In the first embodiment, both the chip interval detection unit 40 and the load detection unit 50 are provided. The control unit 30 may perform feedback control based on the detection results of both, or may perform feedback control based on the detection result of either the chip interval detection unit 40 or the load detection unit 50. The control unit 30 in some examples may not perform any feedback control. If either the chip interval detection unit 40 or the load detection unit 50 are not used for feedback control, then such units may be omitted from a semiconductor manufacturing apparatus 1 in some examples.

The load detection unit 50 may detect the load applied to the expanding tape TP instead of the load applied to the upper rotating body 101 and the lower rotating body 102.

### Comparative Example

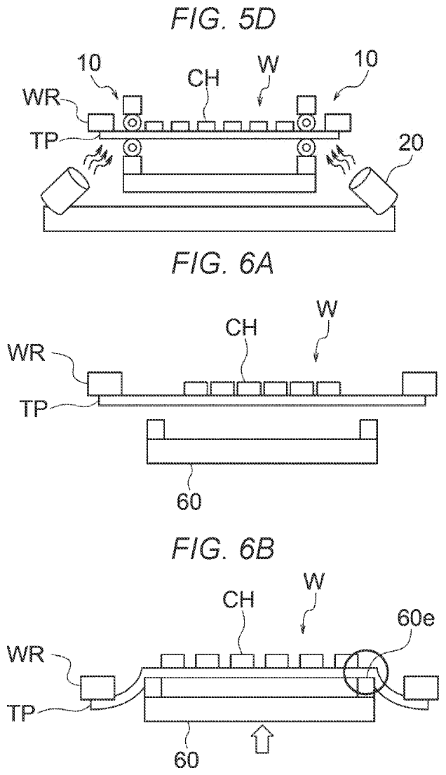

FIGS. 6A to 6C are diagrams illustrating an example of a method of manufacturing a semiconductor device according to a Comparative Example. The Comparative Example differs from the first embodiment in that the interval between the semiconductor chips CH is expanded by pushing up the expanding tape TP from below.

First, as illustrated in FIG. 6A, the semiconductor wafer W is carried (loaded) into the semiconductor manufacturing apparatus 1.

Next, as illustrated in FIG. 6B, the expanding tape TP is stretched (pulled) by pushing up the expanding tape TP from below with a push-up member (pushing-up table) 60. Accordingly, the semiconductor chips CH of the semiconductor wafer W are pulled outward together with the expanding tape TP.

Herein, the more the push-up member 60 pushes upward, the wider the interval between the semiconductor chips CH can be made. However, when the push-up member is pushed up too much, for example, stress concentrates on the portion that is in contact with an end (corner) 60e of the push-up member 60, and there is a possibility that holes occur in the expanding tape TP. There is a possibility that the hole of the expanding tape TP can lead to conveyance errors. The force applied to the expanding tape TP by the push-up member 60 is generally isotropic in the plane. Here, the expanding tape TP is expanded according to the anisotropy of the ease of expansion of the expanding tape TP. That is, there is a possibility that deviation occurs in the expansion of the expanding tape TP, and deviation occurs in the intervals between the semiconductor chips CH in the surface of the semiconductor wafer W.

Next, as illustrated in FIG. 6C, the relaxing portion TP3 of the expanding tape TP in the region between the semiconductor wafer W and the wafer ring WR is heated. In the semiconductor manufacturing apparatus according to the Comparative Example, the push-up member 60 and the heating unit are provided in different devices (units). Therefore, after expanding the interval between the semiconductor chips CH in the tape expanding process of FIG. 6B, it is necessary to convey the semiconductor wafer W to another unit and heat the expanding tape TP. Here, it takes time to heat the expanding tape TP after expanding the interval between the semiconductor chips CH. As a result, there is the possibility that the expanded interval between the semiconductor chips CH may be partially returned (shrunk).

On the other hand, in the first embodiment, the expanding tape TP is veered out by the rotation of the upper rotating body 101 and the lower rotating body 102. Therefore, stress concentration can be reduced by moving the position where the stress acts on the expanding tape TP. In the first embodiment, the rotation of the upper rotating body 101 and the lower rotating body 102 can be controlled for each clamping portion 10 (pair of rotating bodies), that is, according to the direction in the XY plane. Accordingly, deviation in the interval between the semiconductor chips CH due to any anisotropy in the ease of expansion of the expanding tape TP can be reduced or accounted for by load changes. In the first embodiment, the expanding tape TP can be heated while expanding the interval between the semiconductor chips CH. Accordingly, the expanded interval between the semiconductor chips CH can be prevented from being returned.

### Modified Example

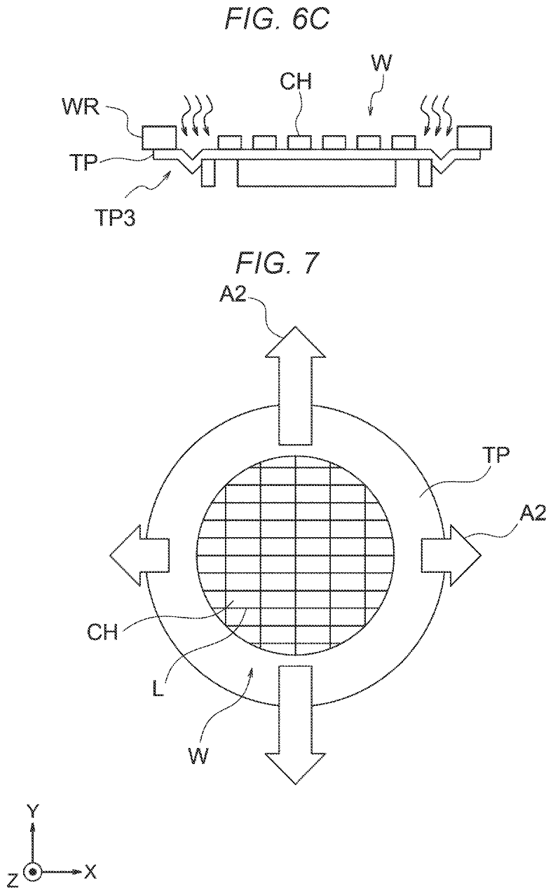

FIG. 7 is a diagram illustrating an example of a shape of a semiconductor chip CH according to a Modified Example. In the Modified Example, the shape of the semiconductor chip CH is different from that of the first embodiment.

In the example illustrated in FIG. 7, the shape of the semiconductor chip CH is a substantially rectangular shape. The X-direction side of the semiconductor chip CH is longer than the Y-direction side of the semiconductor chip CH. Here, the number of lines L expanding the interval between the semiconductor chips CH is also different between an X direction and a Y direction. The line L corresponds to, for example, a dicing line.

The arrows A2 illustrated in FIG. 7 indicate a direction in which the interval between the semiconductor chips CH is to be expanded, that is, a direction in which the expanding tape TP is pulled.

The control unit 30 controls the rotation of the upper rotating body 101 and the lower rotating body 102 for each clamping portion 10 according to the shape of the semiconductor chip CH. The control unit 30 changes the conditions for rotationally driving the upper rotating body 101 and the lower rotating body 102 between the X direction and the Y direction. Accordingly, the force for pulling the expanding tape TP can be different between the X direction and the Y direction. As a result, according to the shape of the semiconductor chip CH or the number of lines L, the interval between the semiconductor chips CH can be expanded more appropriately. In the example illustrated in FIG. 7, the number of lines L expanding in the X direction is larger than the number of lines L expanding in the Y direction. The lines L expanding in the X direction are expanded by the pulling force in the Y direction. Therefore, the lines need to be pulled with stronger force in the Y direction than in the X direction. As in the Modified Example, the shape of semiconductor chip CH may vary. However, the semiconductor manufacturing apparatus 1 according to the Modified Example can obtain the same effects as those of the first embodiment.

### Second Embodiment

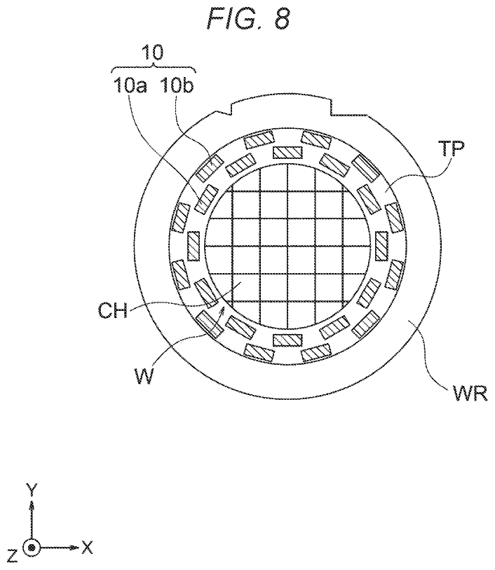

FIG. 8 is a diagram illustrating an example of positioning of a clamping portion 10 according to a second embodiment. In the second embodiment, the positioning of the clamping portions 10 is changed as compared with the first embodiment.

The clamping portions 10 adjacent to each other along the outer circumference of the semiconductor wafer W are disposed so that the distances between the clamping portions 10 and the semiconductor wafer W are different. Each clamping portion 10 includes a clamping portion 10a and a clamping portion 10b. A distance between the semiconductor wafer W and the clamping portion 10a is shorter than a distance between the semiconductor wafer W and the clamping portion 10b. The clamping portions 10a and 10b are alternately disposed along the outer circumference of the semiconductor wafer W. The plurality of clamping portions 10a are disposed concentrically with respect to the semiconductor wafer W. The plurality of clamping portions 10b are disposed concentrically with respect to the semiconductor wafer W.

The clamping portions 10 adjacent along the outer circumference of the semiconductor wafer W overlap each other when viewed from the semiconductor wafer W side. That is, the plurality of clamping portions 10 leave no gap between the clamping portions 10a and 10b when viewed in the pulling direction. Accordingly, for example, the expanding tape TP can be prevented from twisting and forming a hole in the gap between the clamping portions 10a and 10b. As a result, the interval between the semiconductor chips CH can be expanded more appropriately.

The positioning of the clamping portions 10 may be changed as in the second embodiment. The semiconductor manufacturing apparatus 1 according to the second embodiment can obtain effects similar to those of the first embodiment.

### Third Embodiment

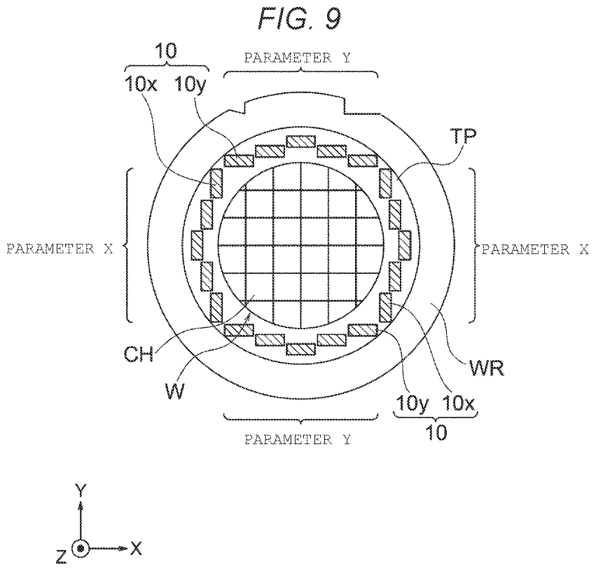

FIG. 9 is a diagram illustrating an example of positioning of a clamping portion 10 according to a third embodiment. In the third embodiment, positioning of the clamping portion 10 is changed compared with the first embodiment.

The clamping portions 10 can be a clamping portion 10x or a clamping portion 10y. The clamping portion 10x and the clamping portion 10y are disposed so that the rotation directions of the upper rotating body 101 and the lower rotating body 102 are different from each other.

The clamping portions 10x are disposed on the sides of the semiconductor wafer W in the X direction. The clamping portions 10y are disposed on the sides of the semiconductor wafer W in the Y direction.

The upper rotating body 101 and the lower rotating body 102 of the clamping portion 10x veer out the expanding tape TP along the X direction parallel to the surface of the expanding tape TP. The upper rotating body 101 and the lower rotating body 102 of the clamping portion 10x rotate about the axis substantially parallel to the Y direction. Accordingly, the clamping portion 10x pulls the expanding tape TP in the X direction.

The upper rotating body 101 and the lower rotating body 102 of the clamping portion 10y veer out the expanding tape TP along the Y direction, which is parallel to the surface of the expanding tape TP and which is different from the X direction. The upper rotating body 101 and the lower rotating body 102 of the clamping portion 10y rotate about the axis substantially parallel to the X direction as the rotation axis. Accordingly, the clamping portion 10y pulls the expanding tape TP in the Y direction.

Different parameters of the upper rotating body 101 and the lower rotating body 102 can be set for the clamping portion 10x and the clamping portion 10y. A parameter X is set as the parameter of the upper rotating body 101 and the lower rotating body 102 of the clamping portions 10x. A parameter Y different from the parameter X is set as the parameter of the upper rotating body 101 and the lower rotating body 102 of the clamping portions 10y. In some examples, feed-back control (automatic adjustment of parameters) using the chip interval detection unit 40 or the load detection unit 50 may be performed.

The positioning of the clamping portions 10 may be changed as in the third embodiment. By changing the direction of rotation of the rotating body, the direction of pulling the expanding tape TP can be changed. The semiconductor manufacturing apparatus 1 according to the third embodiment can obtain effects similar to those of the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus, comprising:
a plurality of clamping portions positioned around an outer circumferential position of a wafer and configured to pull a sheet, to which the wafer is mounted, outwardly from a central portion of the wafer, each clamping portion including a first rotating body paired with a second body for clamping the sheet; and
a control unit configured to control the rotation of each first rotating body of the plurality of clamping portions to pull the sheet outwardly.

2. The semiconductor manufacturing apparatus according to claim 1, wherein the clamping portions are disposed concentrically with respect to the wafer.

3. The semiconductor manufacturing apparatus according to claim 1, wherein the clamping portions are at different distances from the central portion of the wafer.

4. The semiconductor manufacturing apparatus according to claim 1, wherein clamping portions adjacent to each other are at different distances from the central portion of the wafer.

5. The semiconductor manufacturing apparatus according to claim 4, wherein the adjacent clamping portions overlap each other when viewed radially from the central portion of the wafer.

6. The semiconductor manufacturing apparatus according to claim 1, wherein
a first group of clamping portions have first rotating bodies that pull the sheet along a first direction parallel to a surface of the wafer, and
a second group of clamping portions have first rotating bodies that pull the sheet a second direction parallel to the surface of the wafer and different from the first direction.

7. The semiconductor manufacturing apparatus according to claim 1, wherein the control unit controls the rotation of the first rotating body for each clamping portion so that a load on the plurality of clamping portions is uniform.

8. The semiconductor manufacturing apparatus according to claim 1, wherein the control unit controls the rotation of the first rotating body for each clamping portion according to a shape of chips formed on the wafer.

9. The semiconductor manufacturing apparatus according to claim 1, further comprising:
a heating unit configured to heat portions of the sheet beyond the outer circumference of the wafer while the first rotating bodies are being rotated to pull the sheet outwardly from the central portion of the wafer.

10. The semiconductor manufacturing apparatus according to claim 9, wherein the heating unit is rotatable about an axis that passes through substantially the center portion of the wafer.

11. The semiconductor manufacturing apparatus according to claim 1, further comprising:
a load detection unit to detect a load of a first rotating body of one of the plurality of clamping portions, wherein
the control unit controls the rotation of the first rotating body of the one of the plurality of clamping portion based on a detection result from the load detection unit.

12. The semiconductor manufacturing apparatus according to claim 1, further comprising:
a chip interval detection unit to detect an interval between chips formed from the wafer, wherein
the control unit controls the rotation of the first rotating bodies based on a detection result from the chip interval detection unit.

13. The semiconductor manufacturing apparatus according to claim 12, wherein the chip interval detection unit is a laser scanning unit.

14. The semiconductor manufacturing apparatus according to claim 12, wherein the chip interval detection unit is a camera.

15. The semiconductor manufacturing apparatus according to claim 1, wherein the first rotating bodies are a different material than the second members.

16. The semiconductor manufacturing apparatus according to claim 1, wherein, in at least one clamping portion, a shape or size of the first rotating body is different from a shape or size of the second member.

17. The semiconductor manufacturing apparatus according to claim 1, wherein the second member is a rotating body.

18. The semiconductor manufacturing apparatus according to claim 1, wherein the control unit controls each of the plurality of clamping portions by feedback control.

19. A method of manufacturing a semiconductor device, the method comprising:
placing a wafer comprising a plurality of chips in a semiconductor manufacturing apparatus, the wafer being mounted on an expandable sheet; and
using the semiconductor manufacturing apparatus to cause the interval between adjacent chips in the plurality of chips of the wafer to increase by pulling the expandable sheet outwardly from a central portion of the wafer, wherein
the semiconductor manufacturing apparatus includes:
a plurality of clamping portions positioned around an outer circumferential position of the wafer and configured to pull the expandable sheet outwardly from the central portion of the wafer, each clamping portion including a first rotating body paired with a second body for clamping the expandable sheet; and
a control unit to control the rotation of each first rotating body of the plurality of clamping portions to pull the expandable sheet outwardly.

20. The method according to claim 19, further comprising:
dicing the wafer before placing the wafer in the semiconductor manufacturing apparatus.
